(19) United States
(12) Patent Application Publication
(10) Pub. No.: US 2011/0204393 A1
(43) Pub. Date: Aug. 25, 2011

(54) LED LAMP

(75) Inventors: Tatsuya Masumoto, Kyoto (JP); Satoru Masaki, Kyoto (JP); Hironobu Kaneko, Kyoto (JP)

(73) Assignee: ROHM CO., LTD., Kyoto-shi, Kyoto (JP)

(21) Appl. No.: 13/125,904

(22) PCT Filed: Nov. 6, 2009
(86) PCT No.: PCT/JP2009/068970

§ 371 Date: Apr. 25, 2011

(30) Foreign Application Priority Data
Nov. 6, 2008 (JP) 2008-285077
Oct. 19, 2009 (JP) 2009-240893
Oct. 19, 2009 (JP) 2009-240894

(51) Int. Cl. H01L 27/15

(52) U.S. Cl. 257/88; 257/E27.12

(57) ABSTRACT

An LED lamp (A1) includes a plurality of LEDs (2), a retainer (1) on which the light LEDs (2) are mounted, and a wiring pattern formed on the retainer (1) and electrically connected to the LEDs (2). The retainer (1) includes a plurality of substrates (11, 12, 15). Of the plurality of substrates (11, 12, 15), two adjacent substrates (11, 12) are connected to each other by a pair of bendable connection members (32a, 32b). The two substrates (11, 12) are arranged in such a manner that their normal line directions differ from each other.

### TECHNICAL FIELD

The present invention relates to an LED lamp that utilizes a light emitting diode (referred to as “LED” below) as the light source and that can be used as a substitute for an incandescent lamp or a fluorescent lamp.

FIG. 25 is a perspective view showing an example of conventional LED lamp (see Patent Document 1, for example). The LED lamp X shown in the figure includes a disk-like substrate 91, a plurality of LEDs 92 mounted on the disk-like substrate 91, and a base 93 connected to the substrate 91. The LED lamp X is structured such that the LEDs 92 can be turned on by mounting the base 93 to an existing light bulb socket designed for screwing-in a base of an incandescent lamp, for example.

In the LED lamp X, the LEDs 92 are mounted on a single, flat substrate 91, which configuration allows only a limited area to be illuminated. Hence, the LED lamp X, when used in place of an incandescent lamp, may unduly leave a corner of the room badly lit.
Patent Document 1: JP-A-2001-052504

### DISCLOSURE OF THE INVENTION

### Problems to be Solved by the Invention

The present invention has been proposed under the circumstances described above. It is therefore an object of the present invention to provide an LED lamp that is capable of illuminating a wider area.

### Means for Solving the Problems

An LED lamp provided according to the present invention comprises a plurality of light emitting diodes, a retainer on which the light emitting diodes are mounted, and a wiring pattern formed on the retainer and electrically connected to the light emitting diodes. The retainer includes two mount surfaces that are adjacent to each other via a bent portion, and normal line directions of the two mount surfaces are oriented in different directions from each other.

In a preferred embodiment of the present invention, the LED lamp further comprises a support including a plurality of attachment surfaces whose normal line directions are different from each other. The retainer is attached to the support in such a manner that each of the two mount surfaces overlaps a respective one of the attachment surfaces.

Preferably, the attachment surfaces include a central attachment surface that overlaps one of the two mount surfaces. The support has a shape projecting in the normal line direction of the central attachment surface. The support includes a side surface that surrounds the central attachment surface as viewed in the normal line direction of the central attachment surface. Of the plurality of attachment surfaces, the attachment surface that overlaps the other one of the two mount surfaces is provided on the side surface.

More preferably, as the side surface proceeds away from the central attachment surface in the normal line direction of the central attachment surface, the side surface proceeds away from the central attachment surface in a direction perpendicular to the normal line direction of the central attachment surface.

More preferably, the central attachment surface is rectangular, and the side surface comprises a plurality of peripheral attachment surfaces that adjoin sides of the central attachment surface, respectively.

More preferably, the retainer comprises a plurality of separate substrates. The two mount surfaces are obverse surfaces of adjacent two of the plurality of substrates. The bent portion comprises a pair of bendable connection members connecting the two adjacent substrates. The paired connection members electrically connect the wiring patterns formed on the two substrates to each other.

In a preferred embodiment of the present invention, the retainer comprises a rectangular central substrate and a plurality of peripheral substrates separate from the central substrate and surrounding the central substrate. One of the two mount surfaces is an obverse surface of the central substrate, whereas the other one of the two mount surfaces is an obverse surface of the peripheral substrates. The bent portion comprises a pair of bendable connection members connecting the central substrate and each of the peripheral substrates. The paired connection members electrically connect the wiring pattern formed on the central substrate and the wiring pattern formed on the peripheral substrates to each other. The central substrate is attached to the central attachment surface, whereas the peripheral substrates are attached to the peripheral attachment surfaces.

In a preferred embodiment of the present invention, the retainer comprises a flexible wiring substrate. The two mount surfaces are part of an obverse surface of the flexible wiring substrate. The bent portion is formed by bending the flexible wiring substrate.

In a preferred embodiment of the present invention, the retainer comprises a flexible wiring substrate including a rectangular central mount surface that is one of the two mount surfaces and a plurality of peripheral mount surfaces that are the other one of the two mount surfaces and that surround the central mount surface. The bent portion is formed by bending between the peripheral mount surfaces and the central mount surface. The retainer is attached to the support in such a manner that the central mount surface is supported by the central attachment surface and the peripheral mount surfaces are supported by the peripheral attachment surfaces.

In another preferred embodiment of the present invention, the support is in the form of a frustum whose top surface is the central attachment surface. The retainer comprises a flexible wiring substrate including a disk-like central mount surface and a side mount surface surrounding the central mount surface. The bent portion is formed by bending a connection portion between the central mount surface and the side mount surface. The central mount surface and the central attachment surface overlap each other, whereas the side mount surface and the side surface overlap each other.

Preferably, the support is provided with a base for supplying electric power to the light emitting diodes, on an opposite side of the central attachment surface in the normal line direction of the central attachment surface.

Preferably, the support includes a reflective surface provided around the attachment surfaces.

More preferably, the support includes a columnar portion extending between the attachment surfaces and the reflective surface in a direction perpendicular to the reflective surface.

In a preferred embodiment of the present invention, the LED lamp further comprises a globe that includes an opening and houses the light emitting diodes.

More preferably, the inner surface of the globe includes a portion where a radius of curvature reduces as proceeding away from the opening.

More preferably, the globe includes a cylindrical portion and a dome portion connected to the cylindrical portion.

More preferably, the cylindrical portion is tapered.

In a preferred embodiment of the present invention, the LED lamp further comprises a globe that includes an opening and houses the light emitting diodes. The support is in the form of a frustum including a top surface positioned on an opposite side of the opening of the globe and one or a plurality of side surfaces surrounding the top surface. The globe includes an inner surface inclined in the same direction as a direction in which the one or a plurality of side surfaces adjacent thereto are inclined with respect to the top surface.

In another preferred embodiment of the present invention, the LED lamp includes a plurality of light emitting diodes, a foundation portion supporting the light emitting diodes, and a globe that includes an outer surface flush with an outer surface of the foundation portion and allows light emitted from the light emitting diodes to pass through.

In a preferred embodiment of the present invention, the LED lamp further comprises a retainer including a first surface on which at least any one of the light emitting diodes is mounted and a second surface which is oriented in a different direction from the first surface and on which at least any one of the light emitting diodes are mounted. The globe houses the light emitting diodes.

In a preferred embodiment of the present invention, the inner surface of the globe includes a portion where a radius of curvature reduces as proceeding away from the foundation portion.

In a preferred embodiment of the present invention, the globe includes a cylindrical portion including an outer surface that is flush with an outer surface of the foundation portion, and a dome portion connected to the cylindrical portion.

Preferably, the cylindrical portion is tapered.

More preferably, the outer surface of the foundation portion is smooth.

More preferably, the outer surface of the foundation portion is formed with minute irregularities.

In a preferred embodiment of the present invention, current flowing through the light emitting diodes is 20 to 25 mA.

In a preferred embodiment of the present invention, the LED lamp further comprises a support including a plurality of attachment surfaces oriented in different directions. The retainer is attached to the support in such a manner that each of the first and the second surfaces overlaps a respective one of the attachment surfaces.

In a preferred embodiment of the present invention, the retainer comprises a flexible wiring substrate. The first and the second surfaces comprise part of the obverse surface of the flexible substrate. The retainer is placed on the support, with the flexible wiring substrate bent.

### BRIEF DESCRIPTION OF THE DRAWINGS

FIG. 1 is a perspective view showing an LED lamp according to a first embodiment of the present invention;

FIG. 2 is a front view showing part of the LED lamp shown in FIG. 1;

FIG. 3 is a plan view showing part of the LED lamp shown in FIG. 1;

FIG. 4 is a plan view showing a retainer for attachment to the LED lamp shown in FIG. 1;

FIG. 5 is a plan view of a flexible wiring substrate for attachment to an LED lamp according to a second embodiment of the present invention;

FIG. 6 is a perspective view showing an LED lamp according to a third embodiment of the present invention;

FIG. 7 is a plan view showing a flexible wiring substrate used for the LED lamp shown in FIG. 6;

FIG. 8 is a perspective view showing a support used for the LED lamp shown in FIG. 6;

FIG. 9 is a front view of an LED lamp according to a fourth embodiment of the present invention;

FIG. 10 is an exploded perspective view of the LED lamp shown in FIG. 9;

FIG. 11 is a sectional view of the LED lamp shown in FIG. 9;

FIG. 12 is a right side view of the LED lamp shown in FIG. 9;

FIG. 13 is a left side view of the LED lamp shown in FIG. 9;

FIG. 14 is a rear view of the LED lamp shown in FIG. 9;

FIG. 15 is a plan view of the LED lamp shown in FIG. 9;

FIG. 16 is a bottom view of the LED lamp shown in FIG. 9;

FIG. 17 is a development view of a retainer of the LED lamp shown in FIG. 9;

FIG. 18 shows the circuit configuration of the LED lamp shown in FIG. 9;

FIG. 19 is a perspective view of principal portions of the LED lamp shown in FIG. 10;

FIG. 20 is a perspective view showing an LED lamp according to a fifth embodiment of the present invention;

FIG. 21 is a front view showing principal portions of the LED lamp shown in FIG. 20;

FIG. 22 is a plan view of the principal portions, as seen from above in FIG. 21;

FIG. 23 is a development view of a retainer of the LED lamp shown in FIG. 20;

FIG. 24 is a development view of a retainer of the LED lamp according to a sixth embodiment of the present invention;

FIG. 25 is a perspective view showing an example of a conventional LED lamp.

### BEST MODE FOR CARRYING OUT THE INVENTION

Preferred embodiments of the present invention are described below with reference to the accompanying drawings.

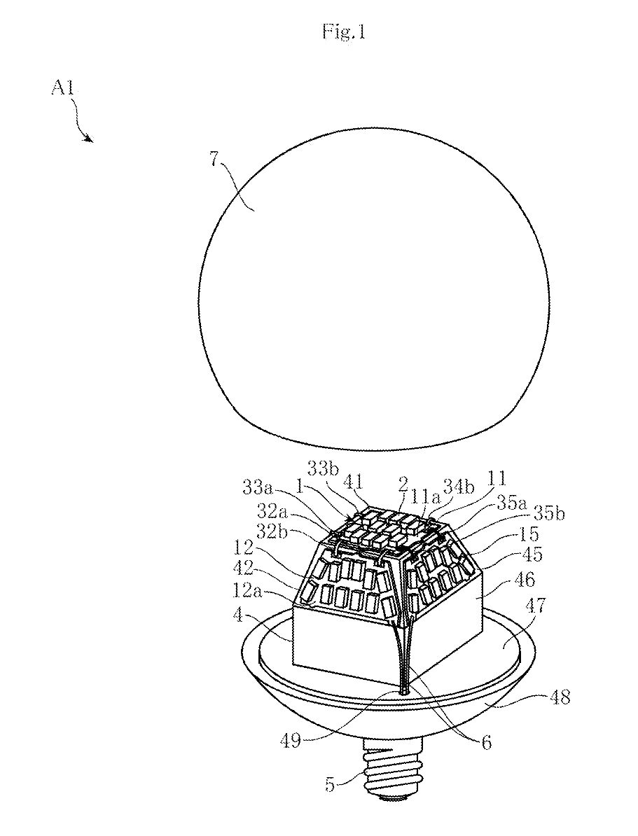

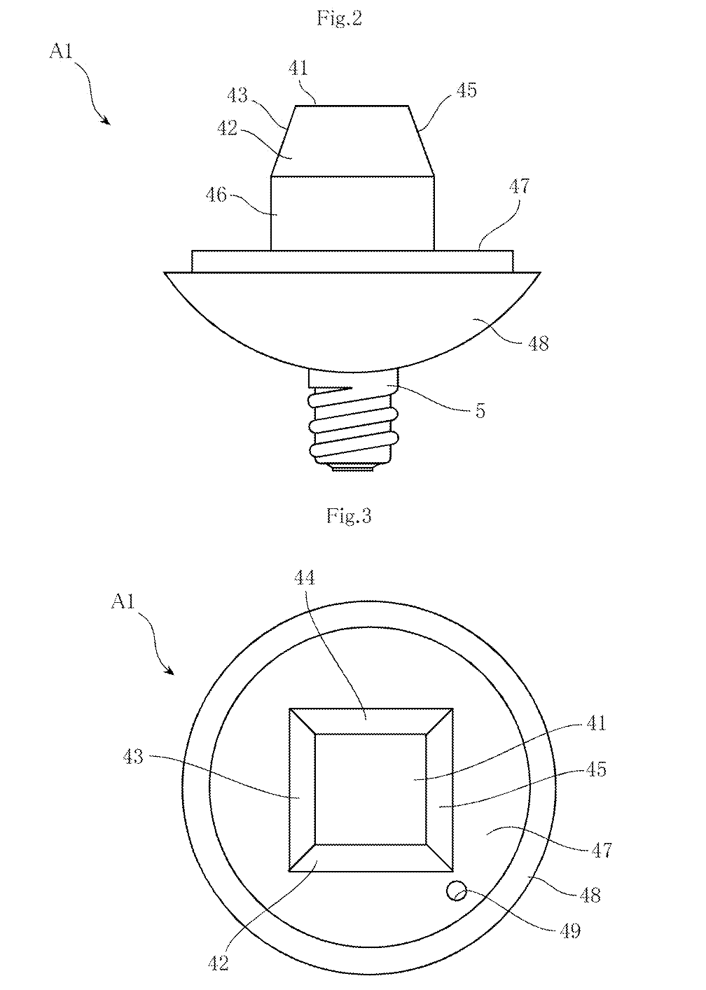

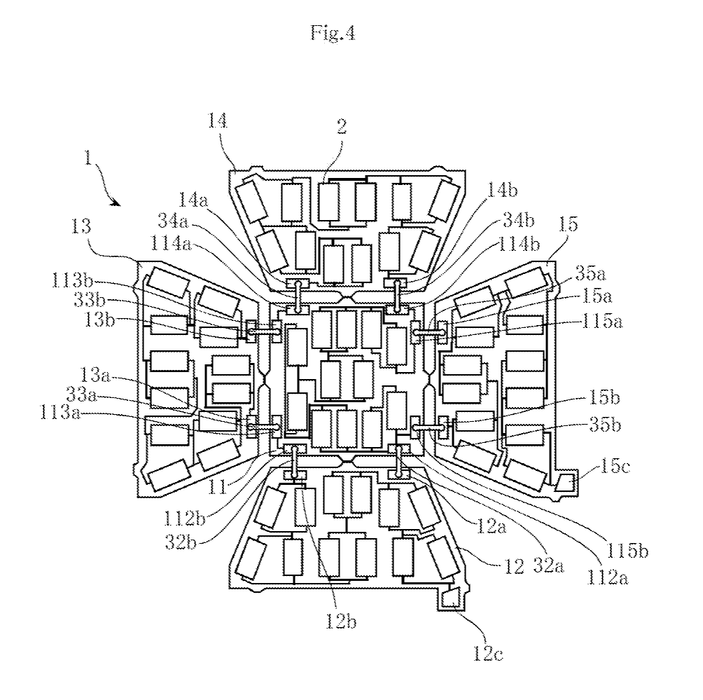

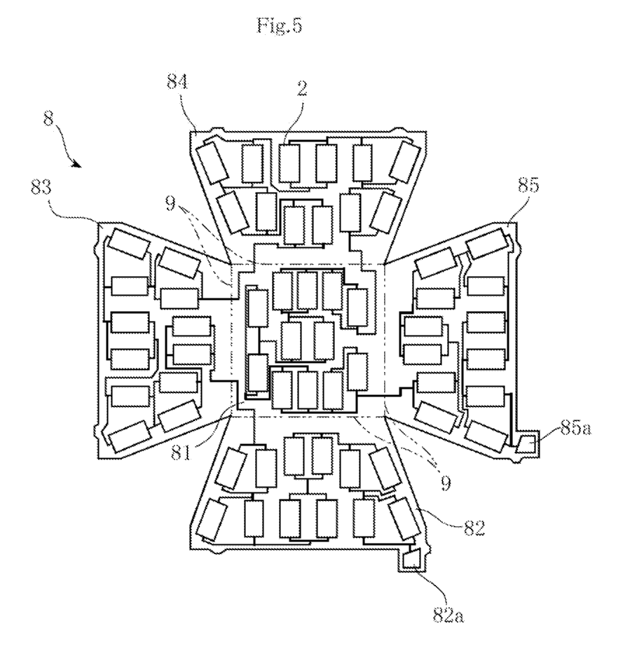

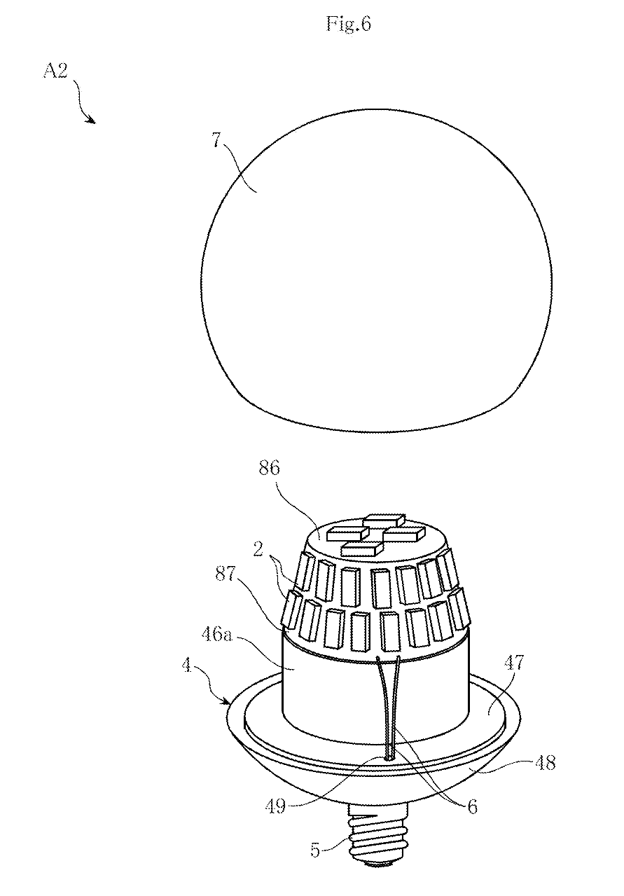

FIG. 1 shows an LED lamp according to a first embodiment of the present invention. The LED lamp A1 shown in FIG. 1 includes a retainer 1, sixty LED modules 2 mounted on the retainer 1, four pairs of connection members 32a, 32b, 33a, 33b, 34a, 34b, 35a, 35b, a support 4, a base 5, two wirings 6 and a cover 7. FIG. 2 is a front view of the support 4. FIG. 3 is a plan view of the support 4, as seen from above in FIG. 1. FIG. 4 is a plan view of the retainer 1 in the state before it is attached to the support 4. The base 5 of the LED lamp A1 is attachable to an existing screw-type bulb socket so that the LED lamp A1 can be used as a substitute for an incandescent lamp.

The retainer 1 comprises a central substrate 11 and four peripheral substrates 12, 13, 14, 15 which are spaced apart from each other. As shown in FIG. 4, the retainer is formed with wiring patterns on the surface. The retainer 1 is further provided with a white protective layer (not shown) covering the wiring patterns. The central substrate 11 and four peripheral substrates 12, 13, 14, 15, which constitute the retainer 1, are formed by cutting out of a single large plate-like substrate made of e.g. glass-fiber-reinforced epoxy resin.

Each LED module 2 incorporates an LED that may have a laminated structure made up of an n-type semiconductor layer, a p-type semiconductor layer, and an active layer sandwiched between these layers. The LED modules are incorporated in the wiring patterns on the retainer 1 to emit light.

As shown in FIG. 4, the central substrate 11 is rectangular in plan view and includes eight electrode pads 112a, 112b, 113a, 113b, 114a, 114b, 115a, 115b. The electrode pads 112a and 115b are electrically connected to each other, so are the electrode pads 112b and 113a, the electrode pads 113b and 114a, the electrode pads 114b and 115a. The central substrate 11 has a mount surface 11a on the obverse side, and twelve LED modules 2 are mounted on the mount surface 11a. The wiring pattern on the central substrate 11 connects the electrode pad 114b, the twelve LED modules 2 and the electrode pad 115b. Specifically, this wiring pattern connects six pairs of parallel-connected LED modules 2 in series.

As shown in FIG. 4, the peripheral substrate 12 has a trapezoidal shape in plan view and is provided with three electrode pads 12a, 12b, 12c. The peripheral substrate has a mount surface 12a on the obverse side, on which twelve LED modules 2 are mounted. The electrode pads 12a and 12b are arranged along a side that is closer to the central substrate 11. The electrode pad 12c is arranged at an end of a side that is farther from the central substrate 11. The wiring pattern on the peripheral substrate 12 connects the electrode pad 12c, the twelve LED modules 2 and the electrode pad 12b. Specifically, this wiring pattern connects six pairs of parallel-connected LED modules 2 in series. The electrode pad 12a is connected to the electrode pad 112a of the central substrate 11 via the connection means 32a. The electrode pad 12b is electrically connected to the electrode pad 112b of the central substrate 11 via the connection means 32b. One of the wirings 6 is connected to the electrode pad 12c.

As shown in FIG. 4, the peripheral substrate 13 has a trapezoidal shape in plan view and is provided with two electrode pads 13a and 13b. The peripheral substrate has a mount surface on the obverse side, on which twelve LED modules 2 are mounted. The electrode pads 13a and 13b are arranged along a side that is closer to the central substrate 11. The wiring pattern on the peripheral substrate 13 connects the electrode pad 13a, the twelve LED modules 2 and the electrode pad 13b. Specifically, this wiring pattern connects six pairs of parallel-connected LED modules 2 in series. The electrode pad 13a is electrically connected to the electrode pad 113a of the central substrate 11 via the connection means 33a. The electrode pad 13b is electrically connected to the electrode pad 113b of the central substrate 11 via the connection means 33b.

As shown in FIG. 4, the peripheral substrate 14 has a trapezoidal shape in plan view and is provided with two electrode pads 14a and 14b. The peripheral substrate has a mount surface on the obverse side, on which twelve LED modules 2 are mounted. The electrode pads 14a and 14b are arranged along a side that is closer to the central substrate 11. The wiring pattern on the peripheral substrate 14 connects the electrode pad 14a, the twelve LED modules 2 and the electrode pad 14b. Specifically, this wiring pattern connects six pairs of parallel-connected LED modules 2 in series. The electrode pad 19a is electrically connected to the electrode pad 114a of the central substrate 11 via the connection means 34a. The electrode pad 14b is electrically connected to the electrode pad 114b of the central substrate 11 via the connection means 34b.

As shown in FIG. 4, the peripheral substrate 15 has a trapezoidal shape in plan view and is provided with three electrode pads 15a, 15b, 15c. The peripheral substrate has a mount surface on the obverse side, on which twelve LED modules 2 are mounted. The electrode pads 15a and 15b are arranged along a side that is closer to the central substrate 11. The electrode pad 15c is arranged at an end of a side that is farther from the central substrate 11. The wiring pattern on the peripheral substrate 15 connects the electrode pad 15b, the twelve LED modules 2 and the electrode pad 15c. Specifically, this wiring pattern connects six pairs of two parallel-connected LED modules 2 in series. The electrode pad 15a is connected to the electrode pad 115a of the central substrate 11 via the connection means 35a. The electrode pad 15b is electrically connected to the electrode pad 115b of the central substrate 11 via the connection means 35b. The other one of the wirings 6 is connected to the electrode pad 15c.

The connection means 32a, 32b, 33a, 33b, 34a, 34b, 35a, 35b are made of e.g. solder mainly composed of Sn, Ag and Cu and bendable. The pair of connection means 32a and 32b connect the central substrate 11 and the peripheral substrate 12. The pair of connection means 33a and 33b connect the central substrate 11 and the peripheral substrate 13. The pair of connection means 34a and 34b connect the central substrate 11 and the peripheral substrate 14. The pair of connection means 35a and 35b connect the central substrate 11 and the peripheral substrate 15.

The support 4 is made of e.g. A1 and includes a central attachment surface 41, peripheral attachment surfaces 42, 43, 44, 45, a prism portion 46, a reflective surface 47 and an outer casing 48. To the lower end of the support 4 is mounted the base 5. The reflective surface 47 and the outer casing 48 are formed with a through-hole 49 for guiding the two wirings 6 to the base 5.

As shown in FIGS. 1 and 2, the central attachment surface 41 is rectangular and provided at the upper end of the support 4. The normal line direction of the central attachment surface 41 is the vertically upward direction in FIGS. 1 and 2. As shown in FIGS. 1 and 2, all the peripheral attachment surfaces 15, 42, 43, 44, 45 are inclined with respect to the central attachment surface 41. As shown in FIG. 3, the peripheral attachment surfaces 42, 43, 44, 45 adjoin the four sides of the central attachment surface 41 and surround the central attachment surface. Each peripheral attachment surfaces 42, 43, 44, 45 has a trapezoidal shape whose upper side is shorter and lower side is longer. Adjacent ones of the peripheral attachment surfaces 42, 43, 44, 45 have a common side. The respective normal line directions of the peripheral attachment surfaces 42, 43, 44, 45 are inclined with respect to the vertically upward direction and oriented in different directions from each other. The peripheral attachment surfaces 42 and 44 extend away from each other as proceeding downward, and also, the peripheral attachment surfaces 43 and 45 extend away from each other as proceeding downward.

The central substrate 11 is attached to the central attachment surface 41 by using e.g. a double-sided adhesive tape. The peripheral substrates 12, 13, 14, 15 are attached to the peripheral attachment surfaces 42, 43, 44, 45 by similarly using a double-sided adhesive tape, for example. Since the normal line directions of the central attachment surface 41 and the peripheral attachment surfaces 42, 43, 44, 45 are different from each other, the normal line directions of the central substrate 11 and the peripheral substrates 12, 13, 19, 15, which are attached to these attachment surfaces, are also different from each other. Because of the inclination of the peripheral attachment surfaces 42, 43, 44, 45, more light from the LED modules 2 mounted on the peripheral substrates 12, 13, 14, 15 is emitted upward than downward in the vertical direction.

The prism portion 46 connects the lower sides of the peripheral attachment surfaces 42, 43, 44, 45 and the reflective surface 47. As shown in FIG. 3, the reflective surface 47 is circular in plan view. The reflective surface 47 is provided for reflecting the light from the LED modules 2 upward.

The outer casing 48 has an outer surface that is painted white, and is designed to provide an appearance similar to that of an existing white light bulb when a cover 7 is attached to the outer casing.

One of the wirings 6 connected to the base 5 is connected to the electrode pad 12c. The wiring pattern on the peripheral substrate 12 connects the electrode pad 12c and the electrode pad 12b. The electrode pad 12b is electrically connected to the electrode pad 13a via the electrode pads 112b, 113a and two connection means 32b, 33a. The wiring pattern on the peripheral substrate 13 connects the electrode pad 13a and the electrode pad 13b. The electrode pad 13b is electrically connected to the electrode pad 14a via the electrode pads 113b, 114a and two connection means 33b, 34a. The wiring pattern on the peripheral substrate 14 connects the electrode pad 14a and the electrode pad 14b. The electrode pad 14b is electrically connected to the electrode pad 114b via the connection means 34b. The wiring pattern on the central substrate 11 connects the electrode pad 114b and the electrode pad 115b. The electrode pad 115b is electrically connected to the electrode pad 15b via the connection means 35b. The wiring pattern on the peripheral substrate 15 connects the electrode pad 15b and the electrode pad 15c. The electrode pad 15c is connected to the other one of the wirings 6 connected to the base 5. With this arrangement, in the LED lamp A1, thirty pairs of parallel-connected LED modules 2 are arranged in series between the two wirings 6. Thus, by mounting the base 5 to a socket for a light bulb, all the sixty LED modules 2 can be turned on.

The advantages of the LED lamp A1 are described below.

According to the present embodiment, since the normal line directions of the central substrate 11 and the peripheral substrates 12, 13, 14, 15 are different from each other, the directions of light emission from the LED module 2 mounted on the central substrate 11 and the peripheral substrates 12, 13, 14, 15 are different from each other. Thus, the LED lamp A1 illuminates a wider area.

According to the present embodiment, the brightness equivalent to a conventional 40 W incandescent lamp can be achieved at a power consumption of 8 W. Further, since the LED lamp A1 is attachable to an existing socket for light bulbs, it can be readily used as a substitute for an incandescent lamp. The use of the LED lamp A1 instead of an incandescent lamp achieves significant energy saving.

According to the present embodiment, before the retainer 1 is attached to the support 4, whether or not the sixty LED modules 2 can be properly turned on can be checked by bringing test electrodes into contact with the electrode pads 12c and 15c. Thus, connection failure in the retainer 1 can be found before the retainer 1 is attached to the support 4, which reduces waste in the manufacturing process. Thus, the LED lamp A1 reduces the manufacturing cost.

According to the present embodiment, the LED modules 2 mounted on the central substrate 11 and the peripheral substrates 12, 13, 14, 15 emit light mainly upward. Thus, blocking of light by the outer casing 48 and the resulting failure of light emission to the outside is unlikely to occur, which is desirable for increasing the amount of light emission from the LED lamp 2.

According to the present embodiment, of the light emitted from the LED modules 2, part of the light traveling downward is reflected upward by the reflective surface 47. This is desirable for increasing the brightness of the LED lamp A1.

According to the present embodiment, the central attachment surface 41 and the peripheral attachment surfaces 42, 43, 44, 45 are spaced apart from the reflective surface 47 and the base 5 due to the presence of the prism portion 46. Thus, part of the light emitted from the LED modules 2 readily passes through the outside of the reflective surface 47 to travel downward of the LED lamp A1. This is desirable for increasing the illumination area of the LED lamp A1.

According to the present embodiment, the retainer 1 is cut out of a single large plate-like substrate, which is desirable for enhancing the productivity of the LED lamp A1.

An LED lamp according to a second embodiment of the present invention is described below. This LED lamp employs a flexible wiring substrate 8 shown in FIG. 4, instead of the retainer 1 of the LED lamp A1. The structures of other parts are the same as those of the foregoing LED lamp, and the illustration and description of these are omitted. The flexible wiring substrate 8 shown in FIG. 4 includes a central mount surface 81 and four peripheral mount surfaces 82, 83, 84, 85, on which sixty LED modules 2 are mounted. As shown in FIG. 4, the wiring pattern on the flexible wiring substrate 8 is designed such that thirty pairs of parallel-connected LED modules 2 are arranged in series between the electrode pad 82a and the electrode pad 82b. The flexible wiring substrate 8 is designed to be attached to the support 4 by bending at a bent portion 9 between the central mount surface 81 and each of the peripheral mount surfaces 82, 83, 84, 85. Specifically, the central mount surface 81 is attached to the central attachment surface 41, and the peripheral mount surfaces 82, 83, 84, 85 are attached to the peripheral attachment surfaces 42, 43, 44, 45.

The use of the flexible wiring substrate 8 also provides an LED lamp that is capable of illuminating a wide area, similarly to the LED lamp using the retainer 1. Unlike the retainer 1, the flexible wiring substrate 8 does not need to use a connection member, so that the manufacturing process is simplified.

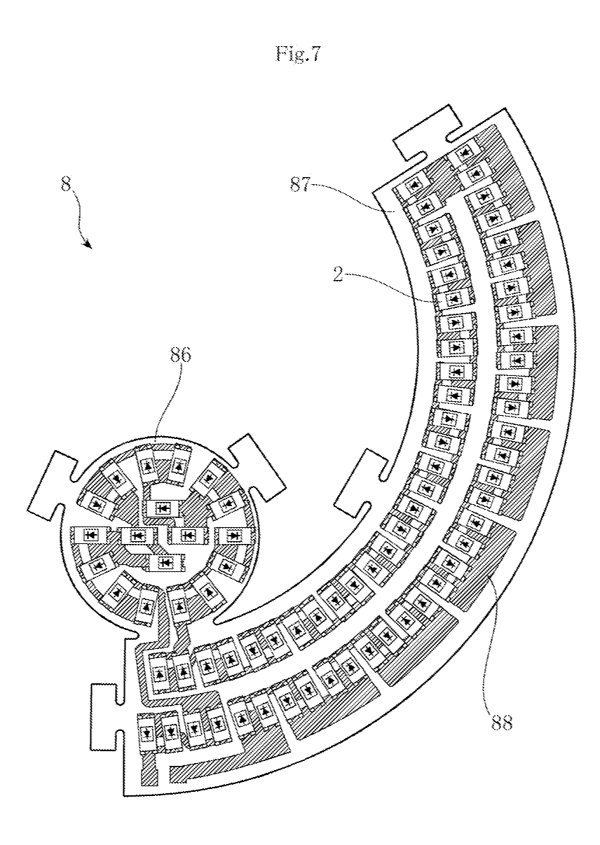

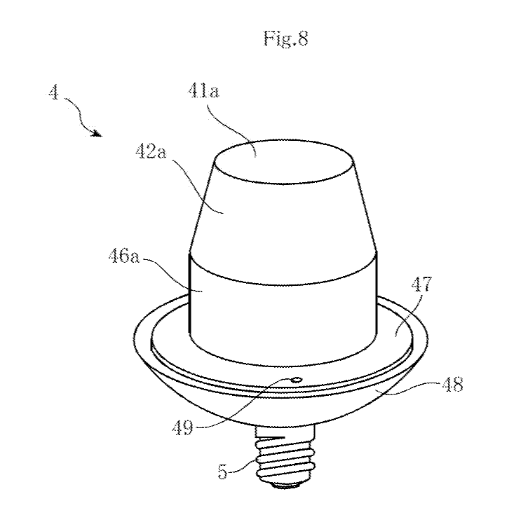

An LED lamp according to a third embodiment of the present invention is described below with reference to FIGS. 6-8. The LED lamp A2 shown in FIG. 6 employs the flexible wiring substrate 8 shown in FIG. 6 instead of the retainer 1 of the LED lamp A1 and also employs a support 4 shown in FIG. 7. The structures of other parts are the same as those of the LED lamp A1. In FIGS. 6-8, the elements that are identical or similar to those of the LED lamp A1 are designated by the same reference signs as those used for the LED lamp A1, and the description is appropriately omitted. The support 4 shown in FIG. 8 comprises a cylindrical portion 46a, which is employed instead of the prism portion 46, and a frustum portion placed on the cylindrical portion 46a. The support 4 further includes a top surface 41a and a side surface 42a of the frustum portion.

As shown in FIG. 7, the flexible wiring substrate 8 of this embodiment includes a central mount surface 86, a side mount surface 87 and a wiring pattern 88. The flexible wiring substrate 8 is attached to the support 4 such that the central mount surface 86 overlaps the top surface 41a and the side mount surface 87 overlaps the side surface 92a. At that time, the connecting portion between the central mount surface 86 and the side mount surface 87 is bent to become a bent portion. The wiring pattern 88 is designed to electrically connect the LED modules 2 to each other. In FIG. 6, the illustration of the wiring pattern 88 and some of the LED modules 2 is omitted.

The use of this flexible wiring substrate 8 also allows the LED lamp to illuminate a wide area, similarly to an LED lamp using the retainer 1. Unlike the retainer 1, the flexible wiring substrate 8 does not need to use a connection member, so that the manufacturing process is simplified.

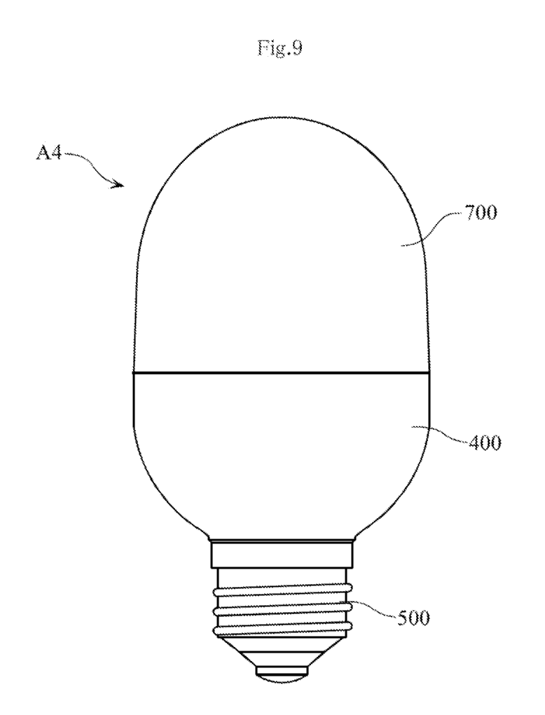

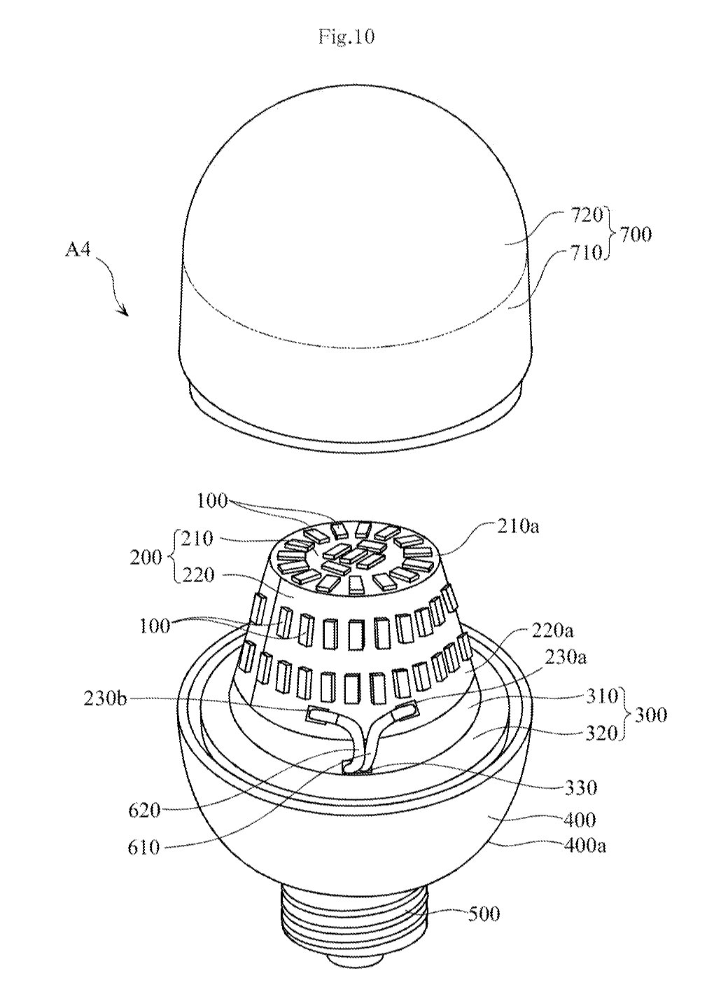

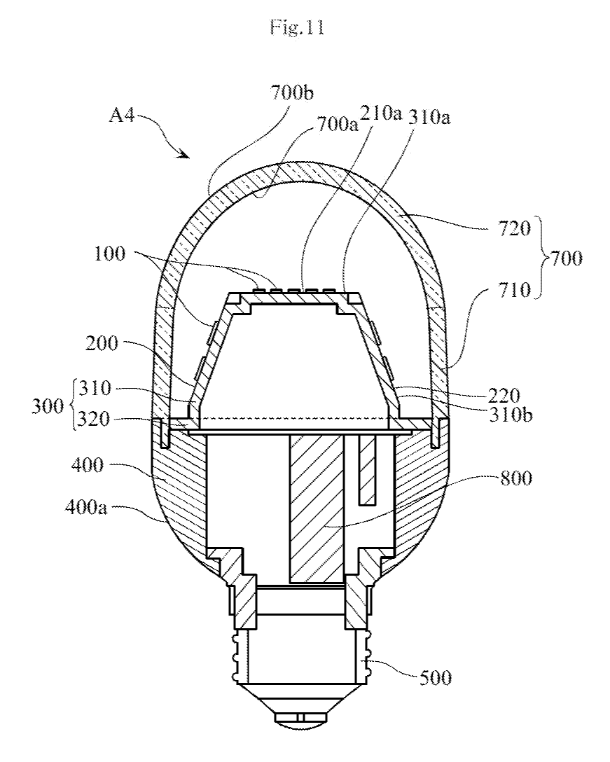

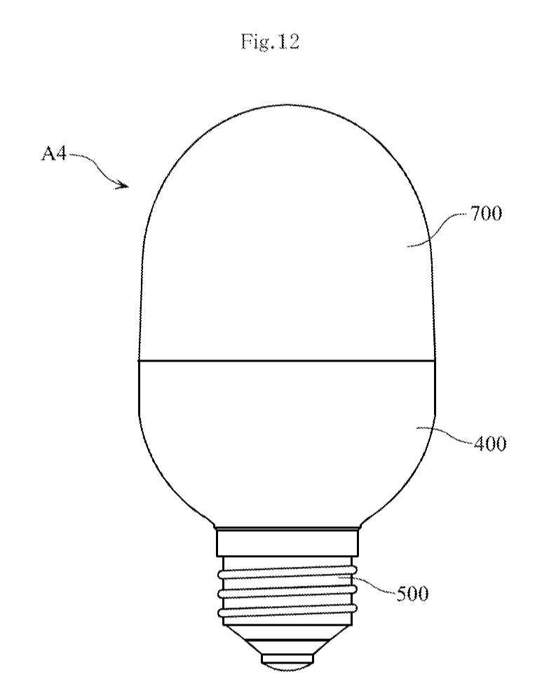

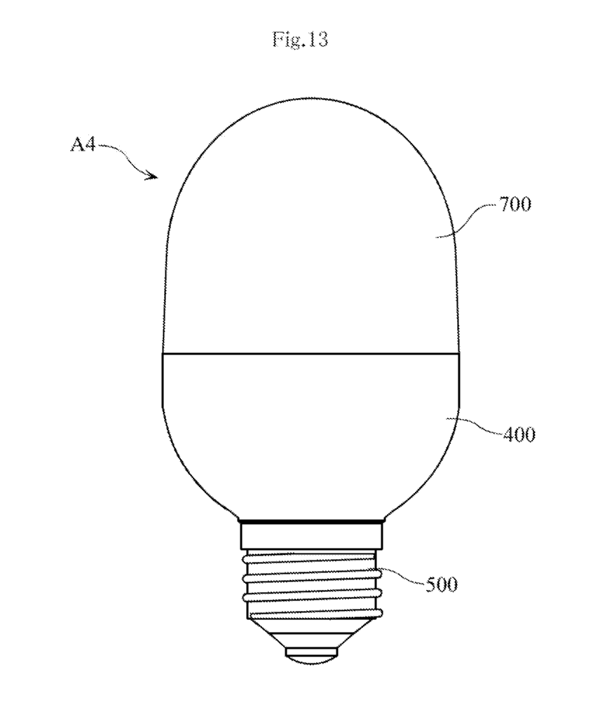

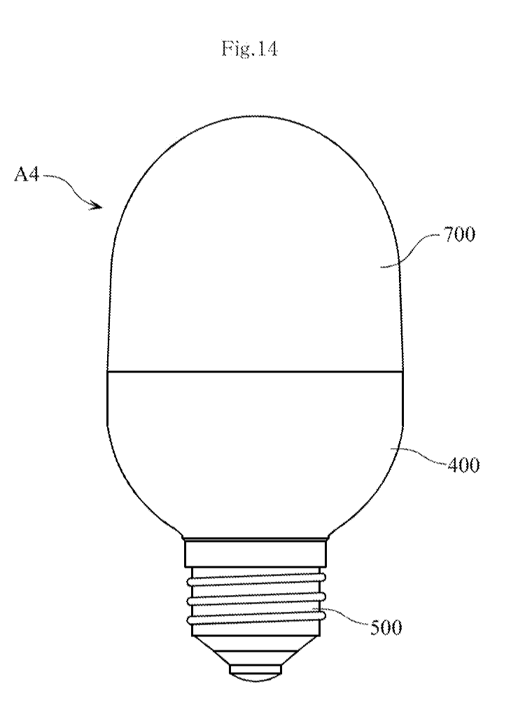

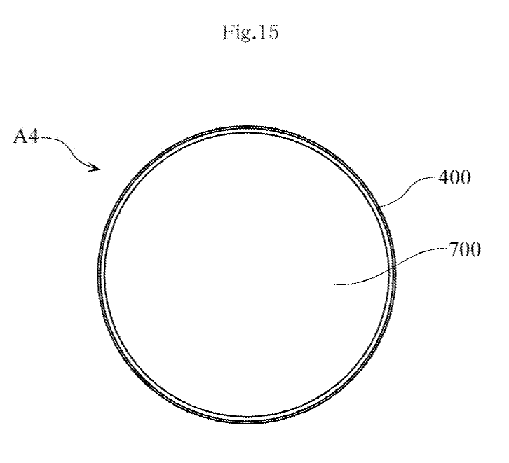

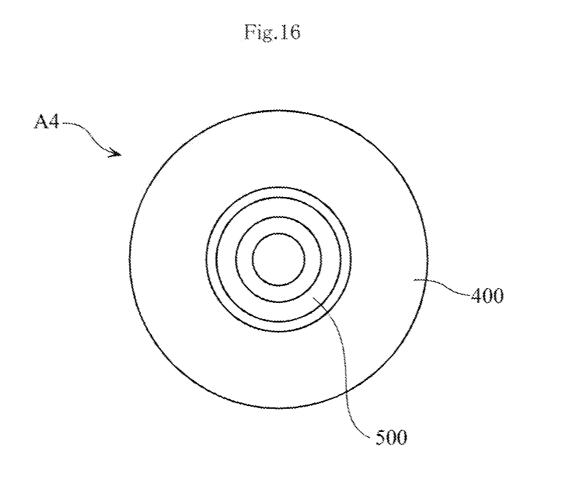

A fourth embodiment of the present invention is described below with reference to FIGS. 9-19. FIG. 9 is a front view of the LED lamp according to the present embodiment. FIG. 10 is an exploded perspective view of the LED lamp according to the present embodiment. FIG. 11 is a sectional view of the LED lamp according to the present embodiment. FIG. 12 is a right side view of the LED lamp according to the present embodiment. FIG. 13 is a left side view of the LED lamp according to the present embodiment. FIG. 14 is a rear view of the LED lamp according to the present embodiment. FIG. 15 is a plan view of the LED lamp according to the present embodiment. FIG. 16 is a bottom view of the LED lamp according to the present embodiment.

The LED lamp A4 shown in these figures includes LED modules 100, a retainer 200, a support 300, a foundation portion 400, a base 500, wirings 610, 620, a globe 700 and a power source unit 800. The base 500 of the LED lamp A4 is attachable to an existing screw-type bulb socket so that the LED lamp A4 can be used as a substitute for an incandescent lamp.

Each LED module 100 incorporates an LED element that may have a laminated structure made up of an n-type semiconductor layer, a p-type semiconductor layer, and an active layer sandwiched between these semiconductor layers.

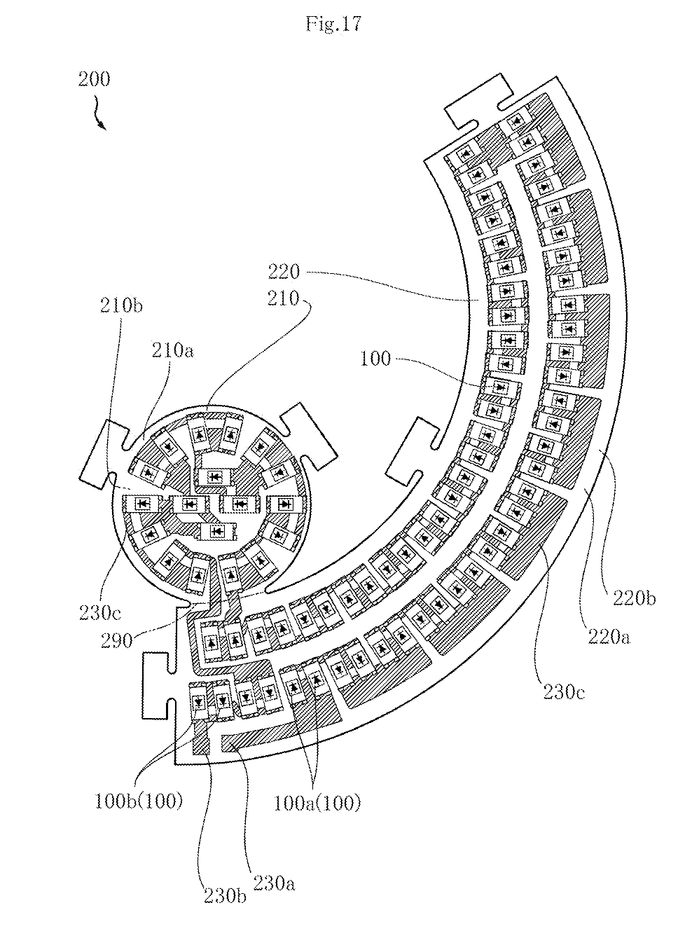

FIG. 17 is a development view of the retainer 200. For the convenience of understanding, the number of LED modules 100 shown in this figure is smaller than the number of LED modules 100 shown in FIG. 10, and the specific arrangement shown in this figure is slightly different from that shown in FIG. 10. In this embodiment, the retainer 200 is a flexible wiring substrate. The retainer 200 includes a top substrate 210, a side substrate 220, electrode pads 230a, 230b, and a wiring pattern 230c. The top substrate 210 is circular and has an obverse surface 210a and a reverse surface 210b. On the obverse surface 210a are mounted the LED modules 100. The side substrate 220 is in the form of a side surface of a frustum and has an obverse surface 220a and a reverse surface 220b. On the obverse surface 220a are mounted the LED modules 100. The electrode pads 230a and 230b are formed on the obverse surface 220a of the side substrate 220. The wiring pattern 230c is formed on the obverse surface 210a of the top substrate 210 and the obverse surface 220a of the side substrate 220.

The obverse surface 210a of the top substrate 210 is a central mount surface of the present invention. The obverse surface 220a of the side substrate 220 is a side mount surface of the present invention.

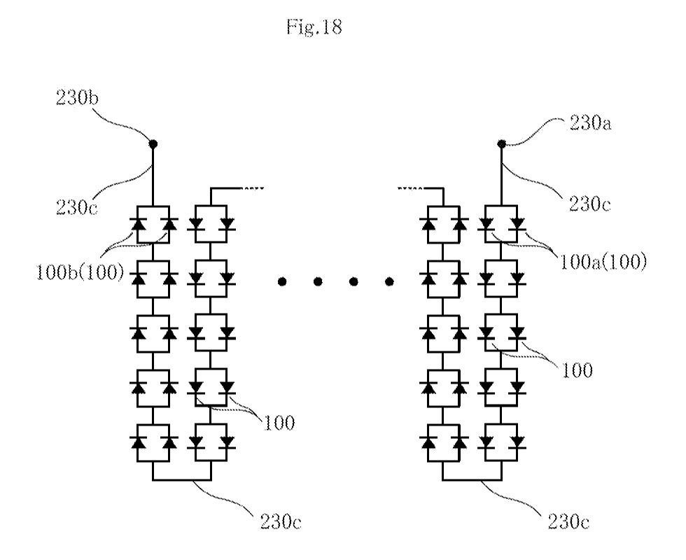

FIG. 18 shows the circuit configuration of the LED lamp according to the present embodiment. As shown in FIGS. 17 and 18, the wiring pattern 230c electrically connects the LED modules 100 to each other. Further, the wiring pattern 230c electrically connects two of the LED modules 100 to the electrode pad 230a. In these figures, the LED modules 100 electrically connected to the electrode pad 230a are designated as LED modules 100a. Further, the wiring pattern 230c electrically connects two of the LED modules 100 to the electrode pad 230b. In these figures, the LED modules 100 electrically connected to the electrode pad 230b are designated as LED modules 100b. As clearly shown in FIG. 18, in the LED lamp A4, a plurality of pairs of parallel-connected LED modules 100 are connected in series from the electrode pad 230a to the electrode pad 230b.

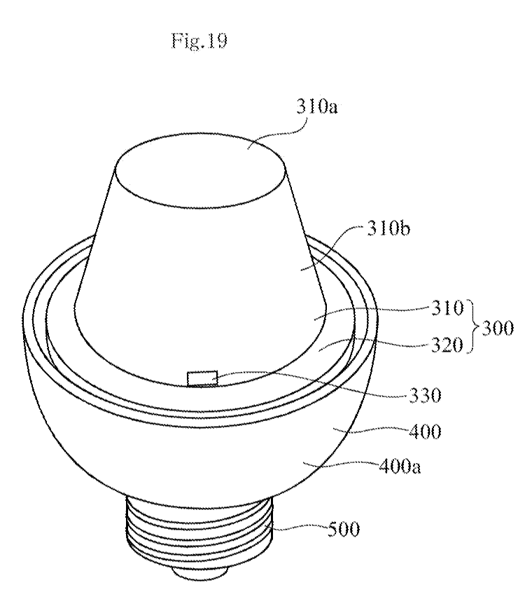

FIG. 19 is a perspective view of principal portions of the LED lamp A4 shown in FIG. 10, and specifically, shows the support 300, the foundation portion 400, and the base 500 only. As shown in FIGS. 10, 11 and 18, the support 300 includes a frustum portion 310 and a bottom plate portion 320. The support 300 is made of a material with high heat dissipation efficiency, such as aluminum. The frustum portion 310 is hollow. The frustum portion 310 includes a top surface 310a and a side surface 310b. The top surface 310a is a central attachment surface of the present invention and supports the top substrate 210 of the retainer 200. Specifically, the top surface 310a and the reverse surface 210b of the top substrate 210 are bonded to each other with e.g. an adhesive. On the side surface 310b, the side substrate 220 of the retainer 200 is placed. Specifically, the side surface 310b and the reverse surface 220b of the side substrate 220 are bonded to each other with e.g. an adhesive. In the retainer 200 in a state attached to the frustum portion 310, the boundary between the top substrate 210 and the side substrate 220 is bent to serve as a bent portion 290. The bottom plate portion 320 is a collar-like member connected to the bottom edge of the frustum portion 310. A rectangular hole 330 is formed at the boundary between the frustum portion 310 and the bottom plate portion 320.

The wiring 610 is electrically connected to the electrode pad 230a. The wiring 610 passes through the hole 330 and is guided into the frustum portion 310. The wiring 620 is electrically connected to the electrode pad 230b. The wiring 620 passes through the hole 330 and is guided into the frustum portion 310.

The foundation portion 400 supports the support 300 and hence supports the LED modules 100. The foundation portion 400 is made of e.g. aluminum. The foundation portion 400 is hollow. The outer surface 400a of the foundation portion 400 is a smooth surface that is not formed with a fin for heat dissipation. The outer surface 400a may have minute irregularities formed by embossing. When the outer surface 400a has such minute irregularities, the height difference among the irregularities may be e.g. 1 to 20 μm. The upper portion of the foundation portion 400 in FIG. 11 tapers as proceeding upward in FIG. 11.

As shown in FIG. 11, the globe 700 is fitted in a gap defined between the foundation portion 400 and the bottom plate portion 320. The globe 700 passes the light emitted from the LED modules 100 from the inner surface 700a to the outer surface 700b. In this embodiment, the globe 700 houses the LED modules 100 in it. The globe 700 is made of e.g. a translucent material. Examples of such a translucent material include polycarbonate. Either one or both of the inner surface 700a and the outer surface 700b may have irregularities formed by embossing. The height difference among such irregularities, when formed, may be e.g. 1 to 20 μm.

The globe 700 includes a cylindrical portion 710 and a dome portion 720. The cylindrical portion 710 tapers as proceeding upward in FIG. 11. The cylindrical portion 710 is tapered such that the outer surface 700b of the globe 700 is connected flush with the outer surface 400a of the foundation portion 400. The dome portion 720 is connected to the cylindrical portion 710. The inner surface 700a includes a portion where the curvature increases as proceeding upward in the figure. (That is, the inner surface 700a includes a portion where the radius of curvature reduces as proceeding upward in the figure.) In this embodiment, the curvature of the inner surface 700a changes at the boundary between the substantially flat inner surface 700a of the cylindrical portion 710 and the substantially spherical inner surface 700a of the dome portion 720.

The present invention includes the structure in which the cylindrical portion 710 is not tapered and the outer surface 700b of the globe 700 and the outer surface 400a of the foundation portion 400 are connected flush with each other.

As shown in FIG. 11, the power source unit 800 is housed in the foundation portion 400. The power source unit 800 includes an AC/DC conversion unit. Electric power is supplied from the outside of the LED lamp 4 to the power source unit 800 via the base 500. The power source unit 800 supplies electric power to the LED modules 100 via the wirings 610 and 620. Thus, light is emitted from each of the LED modules 100.

The advantages of the LED lamp A4 are described below.

In the LED lamp A4, the top substrate 210 is placed on the top surface 310a of the frustum portion 310, and the side substrate 220 is placed on the side surface 310b. The LED modules 100 are mounted on both of the obverse surface 210a of the top substrate 210 and the obverse surface 220a of the side substrate 220. Since the top surface 310a and the side surface 310b of the frustum portion 310 are oriented in different directions from each other, the direction of light emission from the LED modules 100 mounted on the obverse surface 210a and the direction of light emission from the LED modules 100 mounted on the obverse surface 220a are different from each other. Thus, the LED lamp A4 illuminates a wide area.

In the LED lamp A4, the LED modules 100 are mounted not only on the top substrate 210 but also on the side substrate 220. Thus, as compared with the conventional LED lamp X in which the LEDs 92 are mounted on a flat substrate 91, the LED lamp A4 has a larger area for mounting the LED modules 100. Thus, a larger number of LED modules 100 can be mounted in the LED lamp A4. Thus, a given luminance of light emission from the LED lamp A4 can be achieved with reduced amount of current flowing through each of the LED modules 100. Because of the characteristics of LED elements, when a current flowing through a single LED module 100 is reduced, the amount of heat generated from a single LED module 100 reduces at a greater rate than the rate of current reduction. Thus, the total amount of heat generated from the plurality of LED modules 100 reduces. Thus, the LED lamp A4 is suitable for suppressing heat generation. In the LED lamp A4, the current caused to flow to a single LED module 100 is e.g. about 25 to 30 mA. This current value is 41 to 50% of the rated current.

In the LED lamp A4, by causing current to flow between the electrode pad 230a and the electrode pad 230b, whether or not the LED modules 100 include one that cannot be turned on properly can be checked easily. By carrying out this check before attaching the retainer 200 to the support 300, the connection failure in the retainer 200 is found before the retainer 200 is attached to the support 300. Thus, according to the LED lamp A4, the retainer 200 on which an LED module 100 that cannot be turned on is mounted is prevented from being attached to the support 300. This is desirable for reducing waste in the process of manufacturing the LED lamp A4.

In the LED lamp A4, the inner surface 700a of the globe 700 has a portion where the curvature increases as proceeding upward in FIG. 11. Of the inner surface 700a, the portion close to the foundation portion 400 has a relatively small curvature. With this arrangement, a larger distance is secured between the LED modules 100 and the inner surface 700a than when the inner surface 700a is a perfectly spherical surface, for example. When the LED modules 100 are turned on and the LED lamp A4 is seen from the outer surface 700b side of the globe 700, the brightness is not uniform in every portion of the outer surface 700b if the distance between the LED modules 100 and the inner surface 700a is small. In the LED lamp A4, however, since a large distance is secured between the LED modules 100 and the inner surface 700a of the glove 700, non-uniform brightness among portions of the outer surface 700b is avoided.

In the present embodiment, the globe 700 is made up of the cylindrical portion 710 and the dome portion 720. This arrangement is suitable for providing a large distance between the LED modules 100 and the inner surface 700a. Thus, the LED lamp A4 is suitable for avoiding non-uniform brightness among portions of the outer surface 700b.

In the present embodiment, the LED modules 100 are housed in the globe 700. This arrangement also contributes to the achievement of uniform distance between each of the LED modules 100 and the inner surface 700a. This is suitable for avoiding non-uniform brightness among portions of the outer surface 700b.

It is to be noted that the curvature of the inner surface 700a of the globe 700 may change gradually as proceeding upward in FIG. 11, instead of changing at a boundary portion.

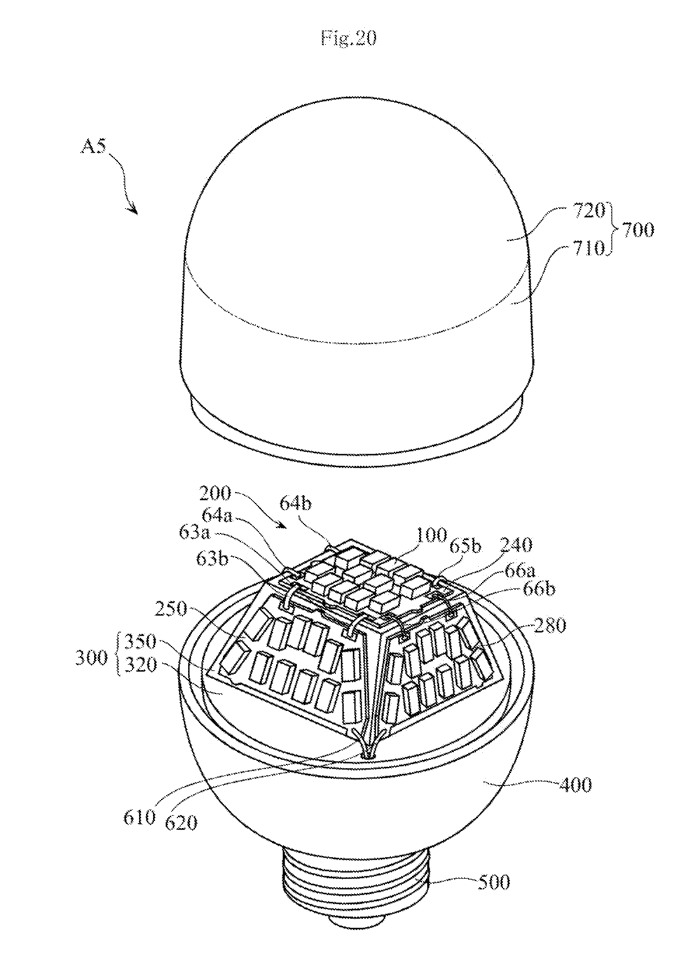

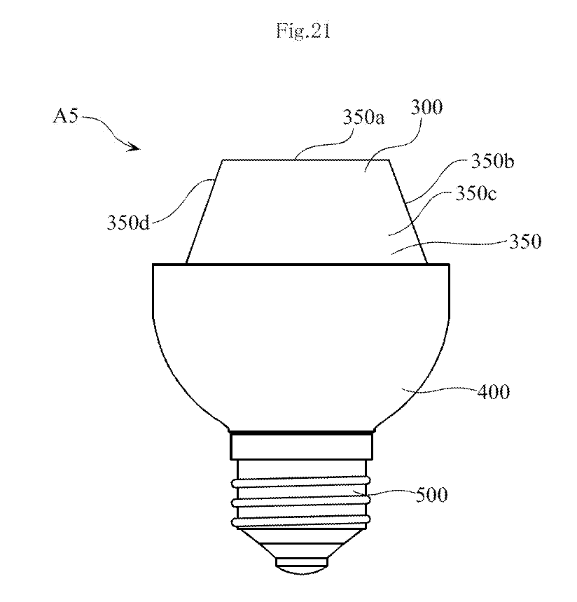

FIGS. 20-23 show a fifth embodiment of the present invention. In these figures, the elements that are identical or similar to those of the fourth embodiment are designated by the same reference signs as those used for the fourth embodiment.

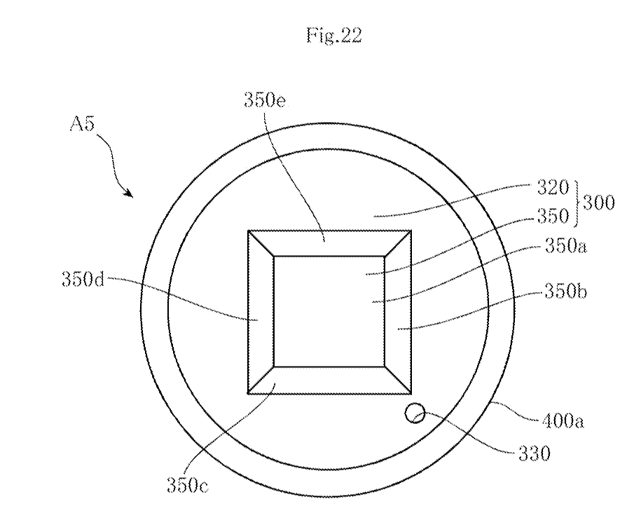

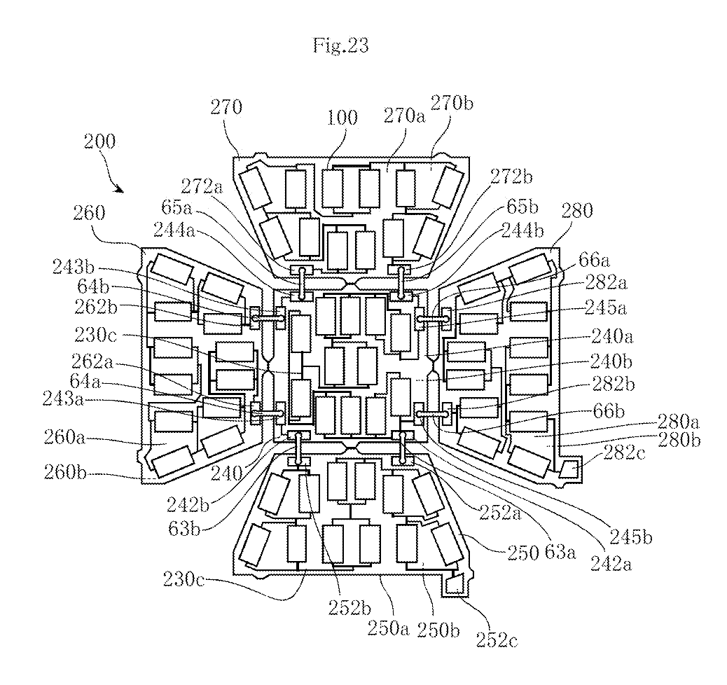

FIG. 20 is a perspective view showing an LED lamp according to the present embodiment. The LED lamp A5 shown in the figure includes LED modules 100, a retainer 200, a support 300, a foundation portion 400, a base 500, wirings 610, 620, eight connection members 63a, 63b, 64a, 64b, 65a, 65b, 66a, 66b, a globe 700 and a power source unit incorporated in the foundation portion 400. The LED lamp A5 is different from the LED lamp A4 mainly in the arrangement of the LED modules 100, in that the retainer 200 is made up of a plurality of plate-like substrates made of a glass-fiber-reinforced epoxy resin, and in that the support 300 is in the form of a truncated pyramid. The specific structures of the foundation portion 400, the base 500, the globe 700, and the power source unit of the LED lamp A5 are the same as those of the LED lamp A4, so that description of these parts are omitted. FIG. 21 is a front view of principal portions of the LED lamp A5 shown in FIG. 20, and specifically shows the support 300, the foundation portion 400, and the base 500 only. FIG. 22 is a plan view of the principal portions, as seen from above in FIG. 21. FIG. 23 is a development view of the retainer 200.

As shown in FIGS. 20 and 23, the retainer 200 includes a central substrate 240, peripheral substrates 250, 260, 270, 280, eight electrode pads 242a, 242b, 243a, 243b, 244a, 244b, 245a, 245b, three electrode pads 252a, 252b, 252c, two electrode pads 262a, 262b, two electrode pads 272a, 272b, three electrode pads 282a, 282b, 282c and a wiring pattern 230c.

The central substrate 240 is rectangular and made of e.g. glass-fiber-reinforced epoxy resin. The central substrate 240 includes an obverse surface 240a and a reverse surface 240b. On the obverse surface 240a are mounted twelve LED modules 100. The eight electrode pads 242a, 242b, 243a, 243b, 244a, 244b, 295a, 245b and the wiring pattern 230c are formed on the obverse surface 240a. The wiring pattern 230c electrically connects the electrode pad 242a and the electrode pad 245b to each other, the electrode pad 242b and the electrode pad 243a to each other, the electrode pad 243b and the electrode pad 244a to each other, and the electrode pad 244b and the electrode pad 245a to each other. The wiring pattern 230c on the central substrate 240 allows current to flow from the electrode pad 244b to the electrode pad 245b through the twelve LED modules 100. The wiring pattern 230c on the central substrate 240 connects six pairs of parallel-connected LED modules 100 in series.

The peripheral substrate 250 has a trapezoidal shape and is made of e.g. glass-fiber-reinforced epoxy resin. The peripheral substrate 250 has an obverse surface 250a and a reverse surface 250b. On the obverse surface 250a are mounted twelve LED modules 100. The three electrode pads 252a, 252b, 252c and the wiring pattern 230c are formed on the obverse surface 250a. Specifically, the electrode pads 252a and 252b are formed on the obverse surface 250a at a portion close to the central substrate 240. The electrode pad 252c is formed at an end of a side that is farther from the central substrate 240. The wiring pattern 230c on the peripheral substrate 250 allows current to flow from the electrode pad 252c to the electrode pad 252b through the twelve LED modules 100. The wiring pattern 230c on the peripheral substrate 250 connects six pairs of parallel-connected LED modules 100 in series.

The peripheral substrate 260 has a trapezoidal shape and is made of e.g. glass-fiber-reinforced epoxy resin. The peripheral substrate 260 has an obverse surface 260a and a reverse surface 260b. On the obverse surface 260a are mounted twelve LED modules 100. The two electrode pads 262a, 262b and the wiring pattern 230c are formed on the obverse surface 260a. Specifically, the electrode pads 262a and 262b are formed on the obverse surface 260a at a portion close to the central substrate 240. The wiring pattern 230c on the peripheral substrate 260 allows current to flow from the electrode pad 262a to the electrode pad 262b through the twelve LED modules 100. The wiring pattern 230c on the peripheral substrate 260 connects six pairs of parallel-connected LED modules 100 in series.

The peripheral substrate 270 has a trapezoidal shape and is made of e.g. glass-fiber-reinforced epoxy resin. The peripheral substrate 270 has an obverse surface 270a and a reverse surface 270b. On the obverse surface 270a are mounted twelve LED modules 100. The two electrode pads 272a, 272b and the wiring pattern 230c are formed on the obverse surface 270a. Specifically, the electrode pads 272a and 272b are formed on the obverse surface 270a at a portion close to the central substrate 240. The wiring pattern 230c on the peripheral substrate 270 allows current to flow from the electrode pad 272a to the electrode pad 272b through the twelve LED modules 100. The wiring pattern 230c on the peripheral substrate 270 connects six pairs of parallel-connected LED modules 100 in series.

The peripheral substrate 280 has a trapezoidal shape and is made of e.g. glass-fiber-reinforced epoxy resin. The peripheral substrate 280 has an obverse surface 280a and a reverse surface 280b. On the obverse surface 280a are mounted twelve LED modules 100. The three electrode pads 282a, 282b, 282c and the wiring pattern 230c are formed on the obverse surface 280a. Specifically, the electrode pads 282a and 282b are formed on the obverse surface 280a at a portion close to the central substrate 240. The electrode pad 282c is formed at an end of a side that is farther from the central substrate 240. The wiring pattern 230c on the peripheral substrate 280 allows current to flow from the electrode pad 282b to the electrode pad 282c through the twelve LED modules 100. The wiring pattern 230c on the peripheral substrate 280 connects six pairs of parallel-connected LED modules 100 in series.

The obverse surfaces 240a, 250a, 260a, 270a and 280a serve as a mount surface of the present invention.

The connection members 63a, 63b, 64a, 64b, 65a, 65b, 66a, 66b are made of e.g. solder mainly composed of Sn, Ag and Cu and bendable. The connection member 63a electrically connects the electrode pad 242a and the electrode pad 252a. The connection member 63b electrically connects the electrode pad 242b and the electrode pad 252b. The pair of connection members 63a and 63b connects the central substrate 240 and the peripheral substrate 250. It is to be noted that the electrode pad 242a and the electrode pad 252a do not need to be electrically connected to each other. However, the connection between the electrode pad 242a and the electrode pad 252a by the connection member 63a strengthens the joint between the central substrate 240 and the peripheral substrate 250.

The connection member 64a electrically connects the electrode pad 243a and the electrode pad 262a. The connection member 64b electrically connects the electrode pad 243b and the electrode pad 262b. The pair of connection members 64a and 64b connects the central substrate 240 and the peripheral substrate 260.

The connection member 65a electrically connects the electrode pad 249a and the electrode pad 272a. The connection member 65b electrically connects the electrode pad 244b and the electrode pad 272b. The pair of connection members 65a and 65b connects the central substrate 240 and the peripheral substrate 270.

The connection member 66a electrically connects the electrode pad 245a and the electrode pad 282a. The connection member 66b electrically connects the electrode pad 245b and the electrode pad 282b. The pair of connection members 66a and 66b connects the central substrate 240 and the peripheral substrate 280. It is to be noted that the electrode pad 245a and the electrode pad 282a do not need to be electrically connected to each other. However, the connection between the electrode pad 245a and the electrode pad 282a by the connection member 66a strengthens the joint between the central substrate 240 and the peripheral substrate 280.

In the LED lamp A5, current flows as follows. First, current flows from the electrode pad 252c to the electrode pad 252b through twelve LED modules 100. Then, the current flows from the electrode pad 252b to the electrode pad 262a through the connection member 63b, the electrode pad 242b, the wiring pattern 230c, the electrode pad 243a and the connection member 64a. Then, the current flows from the electrode pad 262a to the electrode pad 262b through twelve LED modules 100. Then, the current flows from the electrode pad 262b to the electrode pad 272a through the connection member 64b, the electrode pad 243b, the wiring pattern 230c, the electrode pad 244a and the connection member 65a. Then, the current flows from the electrode pad 272a to the electrode pad 272b through twelve LED modules 100. Then, the current flows from the electrode pad 272b to the electrode pad 245a through the connection member 65b, the electrode pad 244b and the wiring pattern 230c. Then, the current flows from the electrode pad 245a to the electrode pad 245b through twelve LED modules 100. Then, the current flows from the electrode pad 245b to the electrode pad 282b through the connection member 66b. Then, the current flows from the electrode pad 282b to the electrode pad 282c through twelve LED modules 100.

In the LED lamp A5, similarly to the LED lamp A4, a plurality of pairs of parallel-connected LED modules 100 are connected in series.

As shown in FIGS. 20-22, the support 300 includes a truncated pyramidal portion 350 and a bottom plate portion 320. The support 300 is made of a material with high heat dissipation efficiency, such as aluminum. The truncated pyramidal portion 350 is hollow. The truncated pyramidal portion 350 includes a top surface 350a and four side surfaces 350b, 350c, 350d, 350e. On the top surface 310a is placed the central substrate 240 of the retainer 200. Specifically, the top surface 310a and the reverse surface 240b of the central substrate 240 are bonded to each other by using e.g. a double-sided adhesive tape. On the side surface 350b is placed the peripheral substrate 250 of the retainer 200. Specifically, the side surface 350b and the reverse surface 250b of the peripheral substrate 250 are bonded to each other by using e.g. a double-sided adhesive tape. Similarly, on the side surface 350c is placed the peripheral substrate 260 of the retainer 200. On the side surface 350d is placed the peripheral substrate 270 of the retainer 200. On the side surface 350e is placed the peripheral substrate 280 of the retainer 200.

In this embodiment, the wiring 610 is connected to the electrode pad 252c, whereas the wiring 620 is connected to the electrode pad 282c.

Similarly to the LED lamp A4, the LED lamp A5 can emit light by the supply of electric power from outside of the LED lamp A5 to the LED modules 100 via the base 500.

Because of the same reasons as described above with respect to the LED lamp A4, the LED lamp A5 can illuminate a wide area. Further, similarly to the LED lamp A4, the LED lamp A5 is also suitable for suppressing heat generation.

The retainer 200 can be formed by cutting out of a single large substrate. This is desirable for enhancing the productivity of the LED lamp A5.

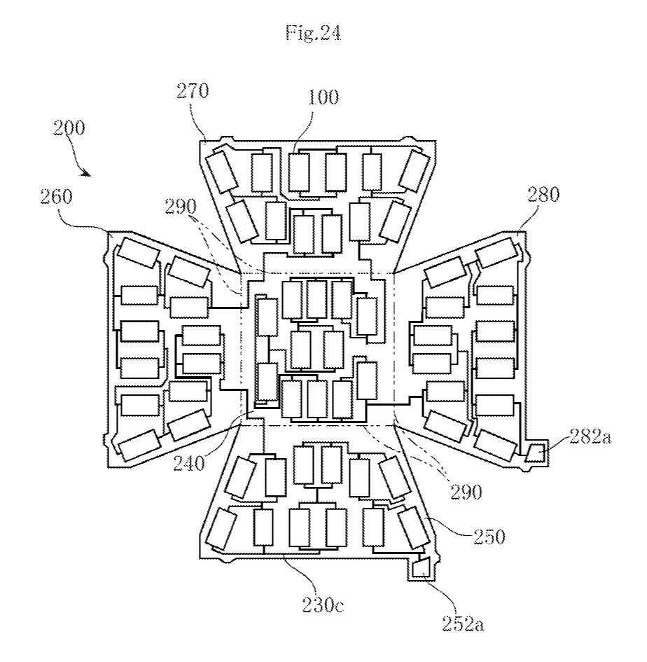

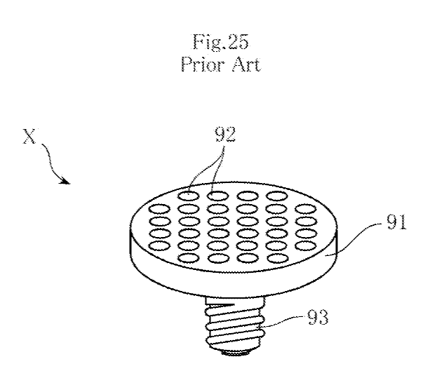

FIG. 24 shows a sixth embodiment of the present invention. In the figure, the elements that are identical or similar to those of the fifth embodiment are designated by the same reference signs as those used for the fifth embodiment.

The LED lamp illustrated in the figure is different from the LED lamp A5 of the fifth embodiment in that a flexible substrate is employed as the retainer 200. The use of a flexible substrate as the retainer 200 eliminates the need for connecting the central substrate 240 and each of the peripheral substrates 250-280 by using a connection member, and the central substrate 240 and each of the peripheral substrates 250, 260, 270, 280 directly connect with each other. In the retainer 200 in a state placed on the support 300 shown in FIG. 20, the boundary between the central substrate 240 and each of the peripheral substrates 250-280 is bent to serve as bent portions 290.

This arrangement provides the same advantages as described above with respect to the LED lamp A4.

The LED lamp according to the present invention is not limited to the foregoing embodiments. The specific structure of each part of the LED lamp according to the present invention may be varied in design in many ways. For instance, although the LED lamp A1 for use as a substitute for an incandescent lamp is described in the embodiments, the present invention is also applicable to an LED lamp for use as a substitute for a straight-tube fluorescent lamp.

An additional LED module may be mounted on the reflective surface 47 to increase the amount of light.

1. An LED lamp comprising:
a plurality of light emitting diodes;
a retainer on which the light emitting diodes are mounted; and
a wiring pattern formed on the retainer and electrically connected to the light emitting diodes;
wherein the retainer includes two mount surfaces that are adjacent to each other via a bent portion, and
normal line directions of the two mount surfaces are different from each other.

2. The LED lamp according to claim 1, further comprising a support including a plurality of attachment surfaces whose normal line directions are different from each other,
wherein the retainer is attached to the support in such a manner that each of the two mount surfaces overlaps one of the attachment surfaces.

3. The LED lamp according to claim 2, wherein the attachment surfaces include a central attachment surface that overlaps one of the two mount surfaces,
the support has a shape projecting in a normal line direction of the central attachment surface, the support including a side surface that surrounds the central attachment surface as viewed in the normal line direction of the central attachment surface, and
the attachment surface of the plurality of attachment surfaces that overlaps the other one of the two mount surfaces is provided on the side surface.

4. The LED lamp according to claim 3, wherein the side surface, as proceeding away from the central attachment surface in the normal line direction of the central attachment surface, proceeds away from the central attachment surface in a direction perpendicular to the normal line direction of the central attachment surface.

5. The LED lamp according to claim 3, wherein the central attachment surface is rectangular, and
the side surface comprises a plurality of peripheral attachment surfaces that adjoin sides of the central attachment surface, respectively.

6. The LED lamp according to claim 1, wherein the retainer comprises a plurality of separate substrates,
the two mount surfaces are obverse surfaces of adjacent two of the plurality of substrates,
the bent portion comprises a pair of bendable connection members connecting said two adjacent substrates, and
the paired connection members electrically connect the wiring patterns formed on the two substrates to each other.

7. The LED lamp according to claim 5, wherein the retainer comprises a rectangular central substrate and a plurality of peripheral substrates separate from the central substrate and surrounding the central substrate,
one of the two mount surfaces is an obverse surface of the central substrate,
the other one of the two mount surfaces is an obverse surface of the peripheral substrates,
the bent portion comprises a pair of bendable connection members connecting the central substrate and each of the peripheral substrates,
the paired connection members electrically connect the wiring pattern formed on the central substrate and the wiring pattern formed on the peripheral substrates to each other,
the central substrate is attached to the central attachment surface, and
the peripheral substrates are attached to the peripheral attachment surfaces.

8. The LED lamp according to claim 1, wherein the retainer comprises a flexible wiring substrate,
the two mount surfaces are part of an obverse surface of the flexible wiring substrate, and
the bent portion is formed by bending the flexible wiring substrate.

9. The LED lamp according to claim 5, wherein the retainer comprises a flexible wiring substrate including a rectangular central mount surface that is one of the two mount surfaces and a plurality of peripheral mount surfaces that are the other one of the two mount surfaces and that surround the central mount surface,
the bent portion is formed by bending between the peripheral mount surfaces and the central mount surface, and
the retainer is attached to the support in such a manner that the central mount surface is supported by the central attachment surface and the peripheral mount surfaces are supported by the peripheral attachment surfaces.

10. The LED lamp according to claim 4, wherein the support is in a form of a frustum whose top surface is the central attachment surface,
the retainer comprises a flexible wiring substrate including a disk-like central mount surface and a side mount surface surrounding the central mount surface,
the bent portion is formed by bending a connection portion between the central mount surface and the side mount surface, and
the central mount surface and the central attachment surface overlap each other, whereas the side mount surface and the side surface overlap each other.

11. The LED lamp according to claim 3, wherein the support is provided with a base for supplying electric power to the light emitting diodes, the base being positioned on an opposite side of the central attachment surface in the normal line direction of the central attachment surface.

12. The LED lamp according to claim 2, wherein the support includes a reflective surface provided around the attachment surfaces.

13. The LED lamp according to claim 12, wherein the support includes a columnar portion extending between the attachment surfaces and the reflective surface in a direction perpendicular to the reflective surface.

14. The LED lamp according to claim 1, further comprising a globe that includes an opening and houses the light emitting diodes.

15. The LED lamp according to claim 14, wherein an inner surface of the globe includes a portion where a radius of curvature reduces as proceeding away from the opening.

16. The LED lamp according to claim 15, wherein the globe includes a cylindrical portion and a dome portion connected to the cylindrical portion.

17. The LED lamp according to claim 16, wherein the cylindrical portion is tapered.

18. The LED lamp according to claim 2, further comprising a globe that includes an opening and houses the light emitting diodes,
wherein the support is in a form of a frustum including a top surface positioned on an opposite side of the opening of the globe and one or a plurality of side surfaces surrounding the top surface, and
the globe includes an inner surface inclined in a same direction as a direction in which said one or a plurality of side surfaces adjacent thereto are inclined with respect to the top surface.
